(19) United States
(12) Patent Application Publication
(10) Pub. No.: US 2011/0054651 A1
(43) Pub. Date: Mar. 3, 2011

(54) AUDIO INPUT UNIT

(75) Inventors: LIN-KUN DING, Shenzhen City (CN); JIANG-FENG SHAN, Shenzhen City (CN); REN-WEN HUANG, Shenzhen City (CN); TSUNG-JEN CHUANG, Tu-Cheng (TW); SHIH-FANG WONG, Tu-Cheng (TW)

(73) Assignees: HONG FU JIN PRECISION INDUSTRY (ShenZhen) CO., LTD, Shenzhen City (TW); HON HAI PRECISION INDUSTRY CO., LTD., Tu-Cheng (TW)

(21) Appl. No.: 12/767,818

(22) Filed: Apr. 27, 2010

(30) Foreign Application Priority Data
Aug. 27, 2009 (CN) 200910306204.7

(51) Int. Cl. G06F 17/00; H03H 7/06

(52) U.S. Cl. 700/94; 333/172

(57) ABSTRACT

An audio input unit, includes an audio capturing unit, a first coupling circuit, a signal filtering circuit, a second coupling circuit, a converting circuit and a codec which are connected in series in that order. The first coupling circuit is used for filtering the direct-current signal, the signal filtering circuit is used for filtering noise from the electrical signal, and the second coupling circuit is used for further filtering the direct-current signal. The converting circuit includes an input port, a first output port and a second output port, when the input port receives the filtered signal, the first output port outputs a signal with the same phase as the filtered signal, the second output port outputs a signal with the reverse phase as the filtered signal, the two output signals have the opposite phase and the same amplitude.

### BACKGROUND

1. Technical Field

The present disclosure relates to electronic devices and, particularly, to an audio input unit.

2. Description of Related Art

In general, portable electronic devices such as mobile phones, media players, digital cameras often have an audio input unit. The audio input unit includes an audio capturing unit, a codec, and an input circuit connected between the audio capturing unit and the codec. Usually, the quality of the audio input unit is determined by the audio capturing unit, the codec, and the input circuit. However, high quality audio capturing unit and codec are expensive, which largely add to the cost of the audio input unit.

Therefore, an audio input unit is desired to overcome the above-described limitations.

### BRIEF DESCRIPTION OF THE DRAWINGS

The components in the drawings are not necessarily drawn to scale, the emphasis instead being placed upon clearly illustrating the principles of the audio input unit. Moreover, in the drawings, like reference numerals designate corresponding parts throughout the several views

FIG. 1 is a block diagram of an audio input unit, in accordance with an embodiment.

FIG. 2 is a circuit diagram of the audio input unit of FIG. 1, in accordance with an embodiment.

### DETAILED DESCRIPTION

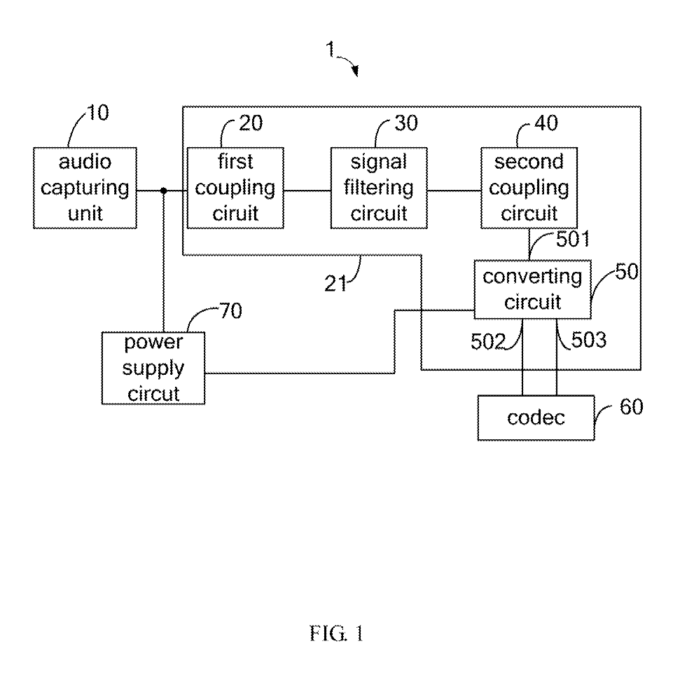

Referring to FIG. 1, an audio input unit 1 includes an audio_{[F1]} capturing unit 10, an input circuit 21, and a codec 60. The input circuit 21 includes a first coupling circuit 20, a signal filtering circuit 30, a second coupling circuit 40, and a converting circuit 50. The audio capturing unit 10, the first coupling circuit 20, the signal filtering circuit 30, the second coupling circuit 40, the converting circuit 50, and the codec 60, are connected in series in that order.

The audio capturing unit 10 is used for capturing audio when turned on and converting the audio into electronic signals. The electronic signals include direct-current signals, first harmonic alternating current signals, second harmonic alternating current signals, third harmonic alternating current signals and other high harmonic alternating current signals. The audio capturing unit 10 can be a microphone, or the like. The first coupling circuit 20 is used for filtering most of direct-current signals of electronic signals from the audio capturing unit 10. The signal filtering circuit 30 is used for filtering out noise of the electronic signals. The noise includes second harmonic, third harmonic, and other high harmonic alternating current signals. The second coupling circuit 40 is used for filtering direct-current signals of electronic signals from the signal filtering circuit 30, then further filtering the direct-current signals of the electronic signals.

The converting circuit 50, includes an input port 501, a first output port 502, and a second output port 503. The input port 501 is connected to the second coupling circuit 40. The first output port 502 is connected to a positive terminal of the codec 60, while the second output port 503 is connected to a negative terminal of the codec 60. When the input port 501 of the converting circuit 50 receives the filtered electronic signal from the second coupling circuit 40, the first output port 502 outputs a signal with the same phase as the filtered electronic signal, the second output port 503 outputs a signal with the reverse phase as the filtered electronic signal. The two output signals have the opposite phase and the same amplitude. Then the two signals inputted to the positive terminal and negative terminal of the codec 60 are differential signals having the opposite phase and the same amplitude. Signal-to-Noise and sensitivity of the signals which inputted to the codec 60 are improved.

The audio input unit 1 further includes a power supply circuit 70 used for supplying power to the audio input unit 1.

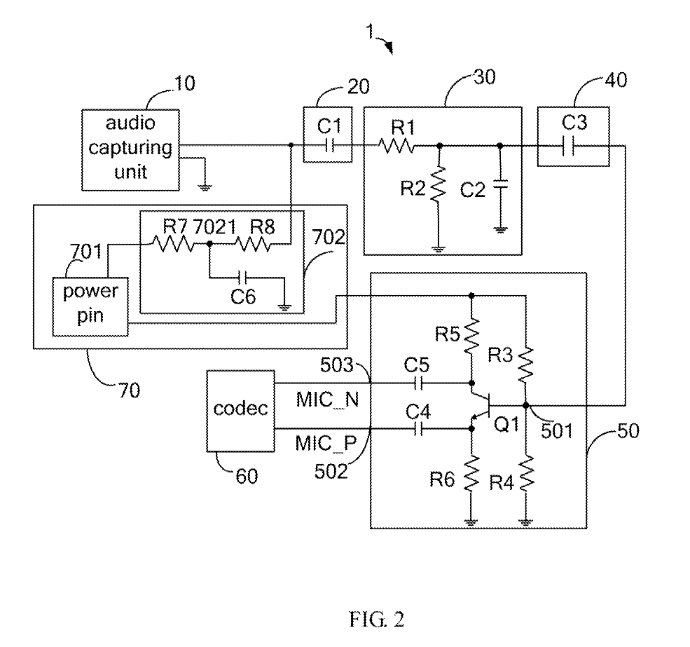

Referring to FIG. 2, the power supply circuit 70 includes a power pin_{[F2]} 701 and a power filtering circuit 702. The power pin 701 is used for connecting to external power source. The power filtering circuit 702 is used for filtering the power obtained by the power pin 701, which includes a first RC low-pass filter and a pull down resistor R8. The first RC low-pass filter includes a resistor R7 and a capacitor C6. A terminal of the pull down resistor R8 is connected to the output port 7021 of the first RC low-pass filter, the other terminal of the pull down resistor R8 is connected to the positive pole of the audio capturing unit 10. When the power pin 701 connects to the external power source, the voltage provided by the external power source is provided to the audio capturing unit 10 after being filtered by the first RC low-pass filter and pulled down by the pull down resistor R8. In the exemplary embodiment, the audio capturing unit 10 is a condenser electret microphone, which captures audio and converts the audio into electronic signals, the negative pole of the microphone is connected to ground, the positive pole is connected to the first coupling circuit 20.

In the circuit, the first coupling circuit 20 includes a capacitor C1 to block most of direct current signals while allowing alternating current signals to pass.

The signal filtering circuit 30 includes a second RC low-pass filter, and a resister R2. The second RC low-pass filter includes a resistor R1 and a capacitor C2. The resister R2 and the capacitor C2 are connected in parallel. The signal filtering circuit 30 is used for filtering out noise of the electronic signals from the first coupling circuit 20, for example, the signal filtering circuit 30 filters out high harmonics and other noise of the electronic signals.

The second coupling circuit 40 includes a capacitor C3. One end of the capacitor C3 is connected to the signal filtering circuit 30. The capacitor C3 further blocks direct-current signals of the electronic signals.

The converting circuit 50 includes a transistor Q1, a first capacitor C4, and a second capacitor C5. The base of the transistor Q1 is connected to the other end of the capacitor C3, and is connected to the power pin 701 via a first resistor R3. The base is connected to ground via a second resistor R4. The emitter of the transistor Q1 is connected to a first terminal of the first capacitor C4, the emitter of the transistor Q1 is further connected to ground via a third resistor R6. The collector of the transistor Q1 is connected to a first terminal of the second capacitor C5, the collector of the transistor Q1 is further connected to the power pin 701 via a fourth resistor R5.

The base of the transistor Q1 serves as the input port 501 of the converting circuit 50 A second terminal of the first capacitor C4 serves as the first output port 502 of the converting circuit 50 and is connected to the positive terminal of the codec 60. A second terminal of the second capacitor C5 serves as the second output port 503 of the converting circuit 50 and is connected to the negative terminal of the codec 60. In the converting circuit 50, the electronic signals will add the direct-current signals from the transistor Q1. The direct-current signals from the transistor Q1 affects Signal-to-Noise and sensitivity of the electronic signals. The first capacitor C4 and the second capacitor C5 are thus used for filtering direct-current signals of the electronic signals output from the emitter and the collector of the transistor Q1.

When the input port 501 of the converting circuit 50 receives filtered electronic signals from the second coupling circuit 40, the first output port 502 outputs a signal with the same phase as the filtered electronic signal, the second output port 503 outputs a signal with the reverse phase as the filtered electronic signal, the two output signals have opposite phase and the same amplitude and are input to the positive terminal and negative terminal of the codec 60. Signal-to-Noise and sensitivity of signals input to the codec 60 are improved. Thus, quality of the audio input unit 1 is improved accordingly.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. An audio input unit, comprising:
an audio capturing unit;
a codec;
a first coupling circuit configured for filtering direct-current signals of electronic signals output from the audio capturing unit;
a signal filtering circuit configured for filtering noise of electronic signals;
a second coupling circuit configured for further filtering direct-current signals of electronic signals; and
a converting circuit comprising an input port, a first output port, and a second output port, the input port connected to the second coupling circuit, the first output port connected to a positive terminal of the codec, the second output port connected to a negative terminal of the codec;
Wherein the audio capturing unit, the first coupling circuit, the signal filtering circuit, the second coupling circuit, the converting circuit and the codec are connected in series in that order, when the input port of the converting circuit receives filtered electronic signals from the second coupling circuit, the first output port outputs a signal with the same phase as the filtered electronic signal, the second output port outputs a signal with the reverse phase as the filtered electronic signal, the two output signals have the opposite phase and the same amplitude.

2. The audio input unit of claim 1, wherein the audio input unit further comprises a power supply circuit, the power supply circuit comprises a power pin and a power filtering circuit, the power pin is used for connecting to an external power source and obtaining power from the external power source, the power filtering circuit is used for filtering the obtained power and providing the filtered power to the audio capturing unit.

3. The audio input unit of claim 2, wherein the power filtering circuit comprises a first RC low-pass filter and a pull down resistor.

4. The audio input unit of claim 2, wherein the converting circuit includes a transistor, a first capacitor, a second capacitor, the base of the transistor is connected to the output terminal of the second coupling circuit, the base of the transistor is also connected to the power pin via a first resistor, and the base of the transistor is further connected to ground via a second resistor; the emitter of the transistor is connected to a first terminal of the first capacitor, the emitter of the transistor is further connected to ground via a third resistor, the collector of the transistor is connected to a first terminal of the second capacitor, the collector of the transistor is further connected to the power pin via a fourth resistor.

5. The audio input unit of claim 4, wherein the base of the transistor serves as the input port of the converting circuit, a second terminal of the first capacitor serves as the first output port of the converting circuit and is connected to a positive terminal of the codec, a second terminal of the second capacitor serves as the second output port of the converting circuit and is connected to a negative terminal of the codec.

6. The audio input unit of claim 1, wherein the first coupling circuit comprises a capacitor.

7. The audio input unit of claim 1, wherein the second coupling circuit comprises a capacitor.

8. The audio input unit of claim 1, wherein the signal filtering circuit comprises a resistor and a second RC low-pass filter, the second RC low-pass filter comprises a resistor and a capacitor.
